(19) United States
(12) Patent Application Publication
(10) Pub. No.: US 2026/0053044 A1
(43) Pub. Date: Feb. 19, 2026

(54) FORMING SEMICONDUCTOR CHIP PACKAGE WITH A SACRIFICAL LAYER

(71) Applicant: TEXAS INSTRUMENTS INCORPORATED, DALLAS, TX (US)

(72) Inventors: Shan HE, CHENGDU (CN); Lin LIN, CHENGDU (CN); Qi Sen GUO, CHENGDU (CN); Zhi Yun LIU, CHENGDU (CN); Bin LIU, SHENYANG (CN); Liu Qiang LIAO, CHENGDU (CN); Jiahui CHEN, CHENGDU (CN)

(21) Appl. No.: 18/804,845

(22) Filed: Aug. 14, 2024

(51) Int. Cl. H01L 23/00; H01L 21/56; H01L 23/498

(52) U.S. Cl. CPC H01L 24/05; H01L 21/56; H01L 24/03; H01L 24/04; H01L 24/48; H01L 23/49838; H01L 2224/0345; H01L 2224/03622; H01L 2224/03831; H01L 2224/04042; H01L 2224/05005; H01L 2224/05084; H01L 2224/05147; H01L 2224/05155; H01L 2224/05166; H01L 2224/05184; H01L 2224/05541; H01L 2224/05664; H01L 2224/48175; H01L 2224/48463; H01L 2924/1815

(57) ABSTRACT

A method of forming an integrated circuit (IC) is provided. The method includes forming a seed layer of a first metal material over a circuit on a device side of a semiconductor die. The method also includes forming a multi-layer conductive contact on the seed layer. The multi-layer conductive contact has a width in a first dimension and includes a plurality of layers of different metal materials and a portion of the seed layer extends outwardly from a periphery of the multi-layer conductive contact. The method further includes forming a sacrificial layer of the first metal material over the multi-layer conductive contact. The method yet further includes etching to remove the seed layer and the sacrificial layer.

### TECHNICAL FIELD

This description relates to fabricating a packaged semiconductor device having a bond over active circuit structure using a sacrificial layer.

### BACKGROUND

A packaged semiconductor device may comprise an active circuit (or more simply a “circuit”) formed over a semiconductor die and coupled to a plurality of conductive terminals via wire bonds. Some semiconductor devices may comprise a bond over active circuit (BOAC) structure including conductive (e.g., metallic) members positioned atop the circuit and coupled to the terminals via the wire bonds.

### SUMMARY

In one example, a method of forming an integrated circuit (IC) is provided. The method includes forming a seed layer of a first metal material over a circuit on a device side of a semiconductor die. The method also includes forming a multi-layer conductive contact on the seed layer. The multi-layer conductive contact has a width in a first dimension and includes a plurality of layers of different metal materials and a portion of the seed layer extends outwardly from a periphery of the multi-layer conductive contact. The method further includes forming a sacrificial layer of the first metal material over the multi-layer conductive contact. The method yet further includes etching to remove the seed layer and the sacrificial layer.

In a second example, another method of forming a bond over active circuit (BOAC) semiconductor device is provided. The method includes forming an insulating layer over a circuit on a device side of a semiconductor die. The insulating layer includes a number of vias separated in a first dimension extending from a first outer via to a second outer via as a via distance. The method also includes forming a seed layer of a first metal material over the insulating layer. The method further includes forming a multi-layer conductive contact electrically coupled to the circuit. The multi-layer conductive contact includes a top surface that is spaced away from the circuit. The multi-layer conductive contact has a contact width in the first dimension and includes a plurality of layers of different metal materials. The method yet further includes forming a sacrificial layer over the multi-layer conductive contact. The sacrificial layer is formed of the first metal material. The method includes performing a metal etch to reduce the seed layer in the first dimension based on the contact width of the multi-layer conductive contact and remove the sacrificial layer. The contact width after the metal etch is greater than the via distance.

In a third example, an IC is provided. The IC includes a circuit on a device side of a semiconductor die. The IC also includes an insulating layer over the circuit. The insulating layer includes a number of vias separated from each other and arranged from a first outer via to a second outer via. The first outer via and the second outer via are spaced apart a via distance. The IC further includes a seed layer of a first metal material over the insulating layer. The IC yet further includes a multi-layer conductive contact over the seed layer and is electrically coupled to the circuit through at least some of the vias. The multi-layer conductive contact includes a top surface that is spaced from the circuit. The multi-layer conductive contact has opposing spaced apart sidewalls that define a contact width that is greater than the via distance.

### BRIEF DESCRIPTION OF THE DRAWINGS

FIG. 1 is a perspective view of a BOAC semiconductor chip package according to some examples.

FIG. 2A is a top view of a conductive member on a semiconductor die of a BOAC semiconductor chip package according to some examples.

FIG. 2B is a cross-sectional view of the conductive member of FIG. 2A according to some examples.

FIGS. 3-17 illustrate operations of a process flow for forming an IC package with a bond pad structure.

FIG. 18 illustrates a flowchart of an example method for fabricating semiconductor device.

FIG. 19 illustrates a table showing the thickness of a sacrificial layer relative to the amount of undercutting of the semiconductor device.

FIG. 20 illustrates a table etching characteristics based on the layer that is etched.

### DETAILED DESCRIPTION

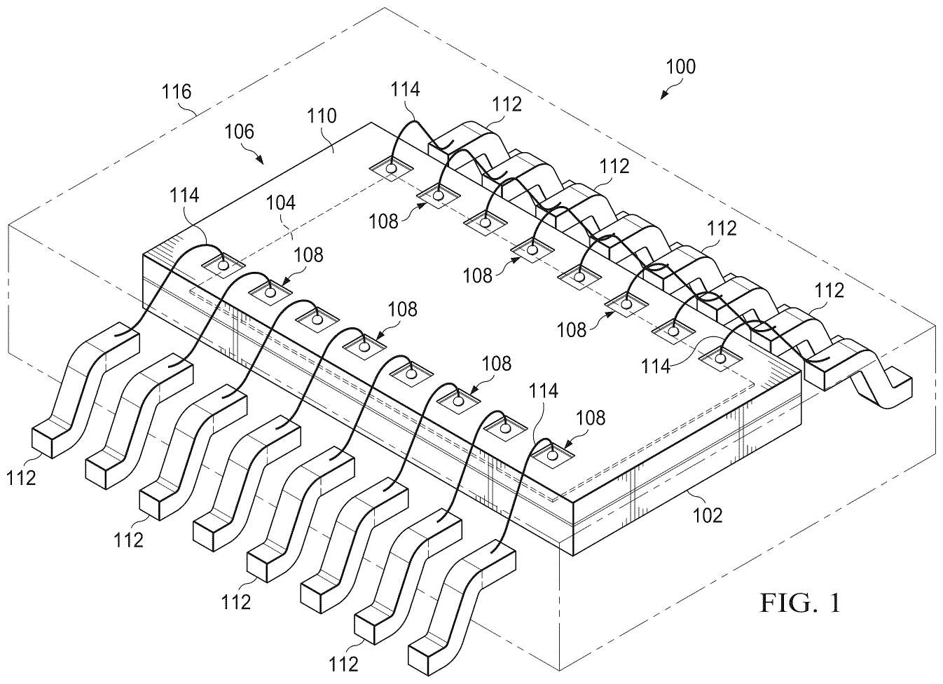

FIG. 1 illustrates an example of a packaged semiconductor device 100. The packaged semiconductor device 100 includes a semiconductor die 102 having an active circuit 104 formed on a device side 106 of the semiconductor die 102. A multi-layer conductive contact including a plurality of conductive members 108 is formed atop of and coupled to the active circuit 104. The conductive members 108 may include a plurality of layers of different metal materials that are positioned within (e.g., embedded in) an insulating layer 110. The insulating layer mitigates electrical shorts between the conductive members 108 during operations. The insulating layer 110 covers at least a portion of the device side 106 of the die 102. In some examples, the conductive members 108 may be coupled to conductive terminals (e.g., pins) 112 by bond wires 114. In other examples, the packaged semiconductor device 100 may include a quad flat no-lead (QFN) package or another package type and the conductive terminals 112 may be arranged and designed for use therein according to the package type. The conductive members 108 of such package would be coupled to the respective conductive terminals 112 by respective bond wires.

A mold compound 116 (e.g., a polymer or resin material) may cover the semiconductor die 102, the bond wires 114, and a portion of the conductive terminals 112. The mold compound 116 may protect the components of packaged semiconductor device 100 from the outside environment (e.g., specifically from dust, liquid, light, contaminants in the outside environment), and may prevent undesired contact with conductive surfaces or members on the packaged semiconductor device 100 during operations.

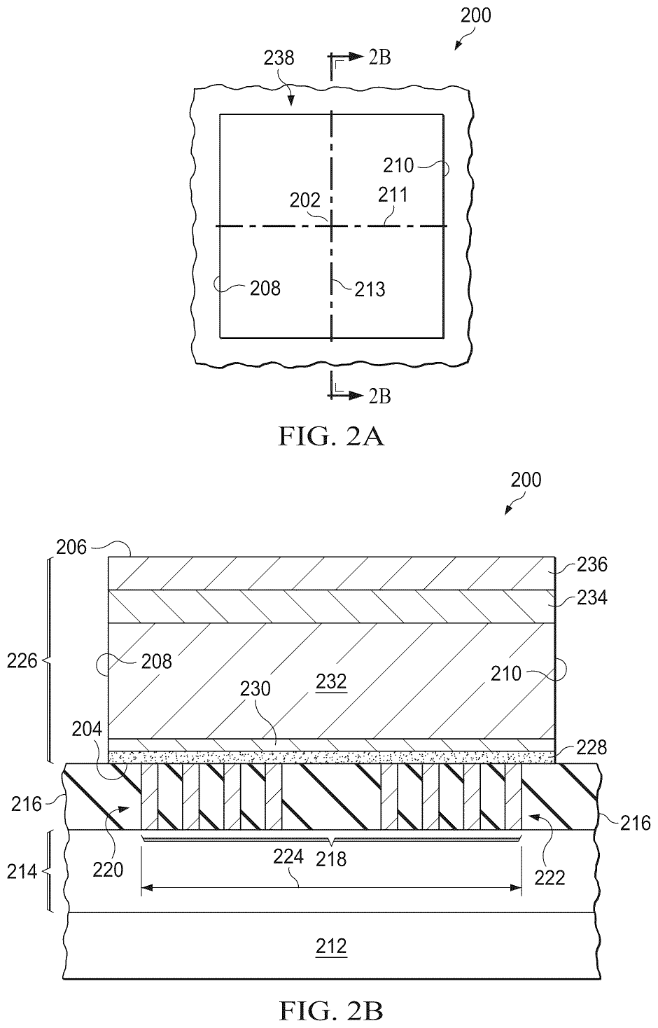

FIG. 2A illustrates a top-down view of a conductive member 200 (e.g., the conductive member 108 of FIG. 1) on the device side (e.g., the device side 106 of FIG. 1) of semiconductor die (e.g., the semiconductor die 102 of FIG. 1).

The conductive member 200 includes a longitudinal axis 202 extending from a bottom surface 204 to a top surface 206, shown in FIG. 2B. FIGS. 2A and 2B employ the same reference numbers to denote the same features. The bottom surface 204 is coupled to an active circuit (e.g. the active circuit 104 of FIG. 1). The top surface 206 is spaced away from the active circuit along longitudinal axis 202. In some examples, longitudinal axis 202 extends normally or perpendicular relative to a plane of the active circuit. A first side surface 208 extends to a second side surface 210 opposite the first side surface 208, defining a width in a first dimension, shown at 211. The first dimension is generally orthogonal to the longitudinal axis 202. The conductive member 200 has a square or generally rectangular cross-section in some examples, such that there is a total of four side surfaces including the first side surface 208 and the second side surface 210. While the first dimension represents a spacing between first and second side surfaces 208 and 210 of the conductive member 200, the first dimension could alternatively extend between opposing side surfaces along a dimension, shown at 213, that is co-planar with and orthogonal to the first dimension 211.

FIG. 2B is a cross-sectional view of the conductive member 200 of FIG. 2A taken along line 2B-2B over an active circuit 212 (e.g., the active circuit 104 of FIG. 1) according to some examples. A number of metal layers 214 are formed over the active circuit 212. The number of metal layers 214 are formed of an electrically conductive material, such as copper, palladium, gold, silver, or other appropriate conductive metal or metal alloy with similar properties. There can be any number of two or more conductive layers to form the conductive member 200. An insulating layer 216 (e.g., the insulating layer 110 of FIG. 1) includes a number of vias 218 that provide an electrical connection to the active circuit 212 through the number of metal layers 214. The insulating layer 216 is formed of one or more insulating materials, such as organic resins (e.g., epoxy), inorganic resins, and/or other suitable materials.

The number of vias 218 are formed of an electrically conductive material, such as copper, palladium, gold, silver, or other appropriate conductive metal or metal alloys with similar properties. The number of vias 218 includes a number of vias separated in the first dimension (e.g., extending along the first dimension 211 of FIG. 2A) extending from an outer surface of a first outer via 220 to an outer surface of a second outer via 222. An outer via is a via of the number vias 218 that is spaced the greatest distance from the longitudinal axis 202 in one direction of the first dimension. An outer surface of a via is a surface that extends in a second dimension, parallel to the longitudinal axis 202, of that via, which is the greatest distance from the longitudinal axis 202. The distance in the first dimension between the outer surfaces of the first outer via 220 and the second outer via 222 is a via distance 224 in a first dimension.

The conductive member 200 has a BOAC structure 226 coupled to the active circuit 212. The BOAC structure 226 includes an adhesion layer 228. The adhesion layer 228 may include metals which have good adhesion of the BOAC structure 226 to the insulating layer 216. For example, the adhesion layer 228 is formed of titanium (Ti) or titanium-tungsten (TiW) and may be formed by a sputter process. The BOAC structure 226 may also include a seed layer 230 formed over the adhesion layer 228. The seed layer 230 provides a suitable electrically conductive surface for a subsequent electroplating operation. The seed layer 230 may include nickel (Ni) or copper (Cu), for example, and may be formed by a sputter process or an evaporation process.

The BOAC structure 226 includes a multi-layer conductive contact electrically coupled to the active circuit 212. The multi-layer conductive contact includes a plurality of different metal layers. For example, the multi-layer conductive contact includes a first layer 232 of the first metal material over the bottom surface 204. In some examples, the first metal material is Cu. A second layer 234 of a second metal material is formed over the first layer 232. For example, the second metal material is Ni. A third layer 236 of a third metal material is formed over the second layer 234. For example, the third metal material is palladium (Pd). The second layer 234 and the third layer 236 protect the first metal material of the first layer 232 from oxidation.

The plurality of side surfaces of the BOAC structure 226, including the first side surface 208 and the second side surface 210, of the layers 232-236 define a periphery 238 of the BOAC structure 226, shown in FIG. 2A. The adhesion layer 228, the seed layer 230, the first layer 232, the second layer 234, and the third layer 236 of the BOAC structure 226 are etched to extend from the first side surface 208 to the second side surface 210. Over-etching the first side surface 208 or the second side surface 210 can etch into the insulating layer and, in some cases, into the number of vias 218. For example, over etching the first side surface 208 beyond the outer surface of the first outer via 220 can lead to the via material being etched out of the first outer via 220. To reduce or prevent over-etching, a sacrificial layer is formed over the third layer 236 during formation of the semiconductor device. The sacrificial layer can be formed of the same material as the seed layer 230 and/or the first layer 232 layer, which helps reduce (or prevent) such over etching because the sacrificial layer acts as a protective layer that avoids the exposure of the third layer 236 thereby minimizing the galvanic effect which reduces the undercut into the first layer 232 during etching.

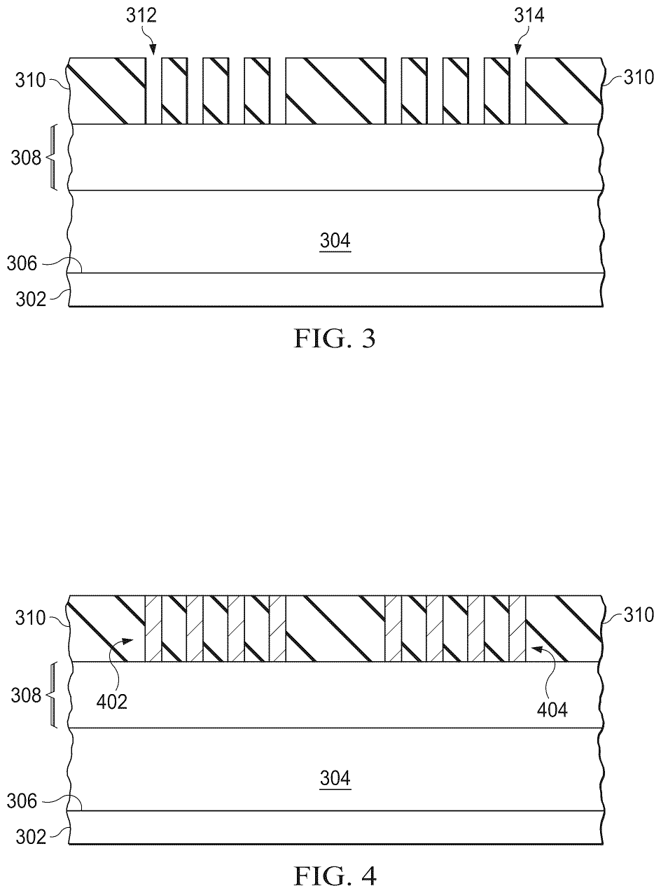

FIGS. 3-16 illustrate stages (e.g., parts) of a process flow for forming a packaged semiconductor device, such as the packaged semiconductor device 100 of FIGS. 1A and 1B having the BOAC structure 226 shown in FIGS. 2A and 2B. To produce the packaged semiconductor device a sacrificial layer is used. For purposes of simplification, FIGS. 3-17 employ the same reference numbers to denote the same structure.

FIG. 3 illustrates an example of a first stage of a process flow of forming a semiconductor device using a sacrificial layer. A semiconductor die 302 has an active circuit 304 (e.g., the active circuit 104 of FIG. 1, the active circuit 212 of FIG. 2B) formed on a device side 306 (e.g., the device side 106 of FIG. 1) thereof. A number of metal layers 308 (e.g., the number metal layers 214 of FIG. 2B) is formed over the active circuit 304. An insulating layer 310 (e.g., the insulating layer 110 of FIG. 1, the insulating layer 216 of FIG. 2B) includes a number of voids including a first outer void 312 and a second outer void 314. As one example, the voids 312, 314 may be formed in the insulating layer 310 by etching the insulating layer 310 using a photomask or photoresist layer.

FIG. 4 illustrates an example of a second stage of the process flow. In the second stage, the voids, including the first outer void 312 and a second outer void 314 are filled with a conductive material to form vias, such as a first outer via 402 (e.g., the first outer via 220 of FIG. 2B) and a second outer via 404 (e.g., the second outer via 222 of FIG. 2B). For example, the conductive material may be Cu. As one example, the voids 312, 314 are filled with the conductive material using a deposition or sputtering process.

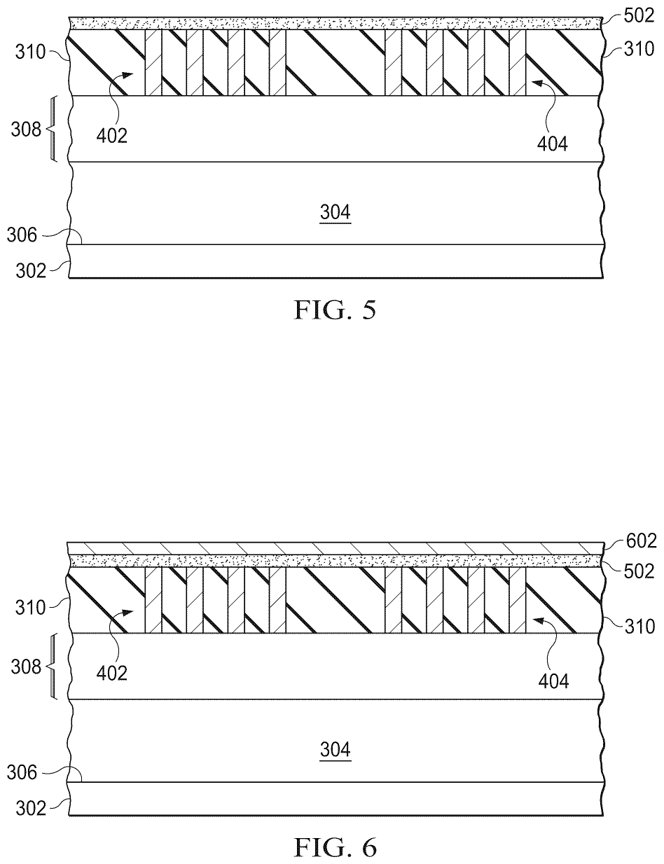

FIG. 5 illustrates an example of a third stage of the process flow. In the third stage, an adhesion layer 502 (e.g., the adhesion layer 228 of FIG. 2B) is applied over the insulating layer 310 having the vias. For example, the adhesion layer 502 may be formed by a sputter process or an evaporation process. In some examples, the adhesion layer 502 is formed of titanium (Ti) or titanium-tungsten (TiW) that is sputtered over the insulating layer 310. For example, the titanium is co-sputtered with tungsten over the epoxy resin of the insulating layer 310.

FIG. 6 illustrates an example of a fourth stage of the process flow. In the fourth stage, a seed layer 602 (e.g., the seed layer 230 of FIG. 2B) is formed by sputtering a seed metal material over the adhesion layer 502. The seed layer 602 provides an electrically conductive surface for a subsequent electroplating operation. The seed metal material may include Ni or Cu based on the first metal material being used to form a BOAC structure (e.g., the BOAC structure 226 of FIG. 2B).

The seed layer 602 has a seed thickness in the second dimension and is the height of the seed layer 602 along the longitudinal axis (e.g., the longitudinal axis 202 of FIGS. 2A, 2B). As one example, the seed thickness of the seed layer 602 is from 800 to 1500 Angstroms (from 0.08 to 0.15 micrometers—μm). The seed thickness provides a sufficient seed thickness of a metal material for plating additional metal. For example, a seed layer 602 of Cu provides sufficient Cu for plating additional Cu.

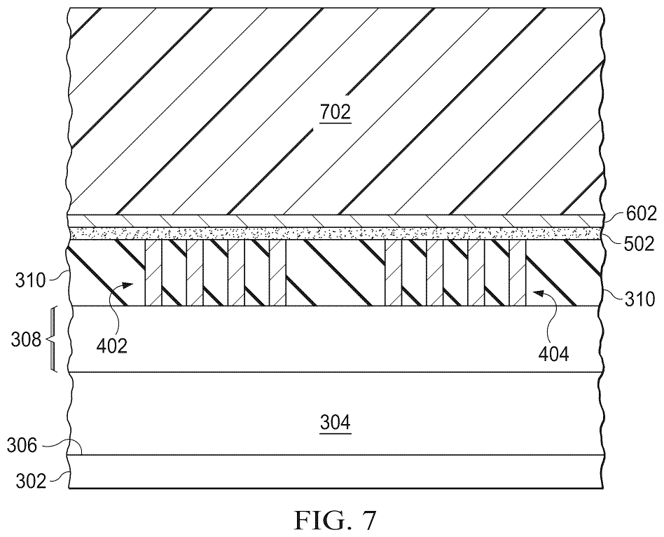

FIG. 7 illustrates an example of a fifth stage of the process flow. In the fifth stage, a photoresist layer 702 is formed on the seed layer 602, such as by spin coating or another application method. The photoresist layer 702 is formed of a photoresist material that is a light-sensitive material. In some examples, the photoresist layer 702 is a negative photoresist.

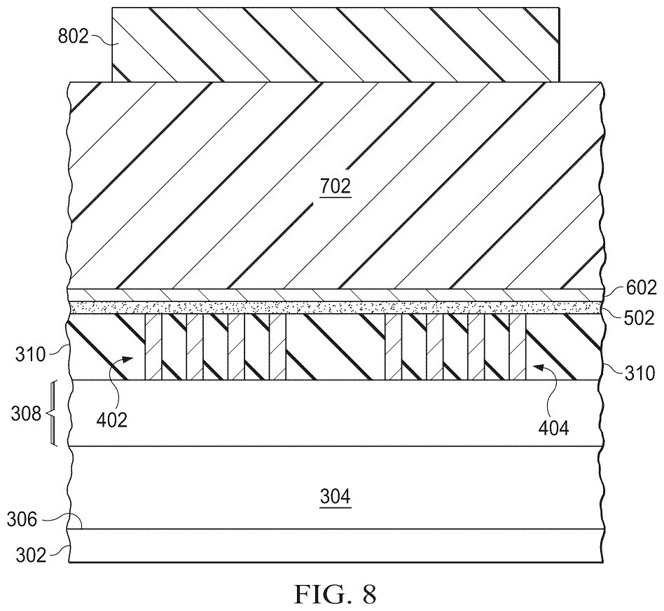

FIG. 8 illustrates an example of a sixth stage of the process flow. In the sixth stage, a photomask 802 is applied to the photoresist layer 702 and the photoresist layer 702 and the photomask 802 are irradiated selectively. Portions of the photoresist layer 702 that are obscured by the photomask 802 are nonirradiated portions.

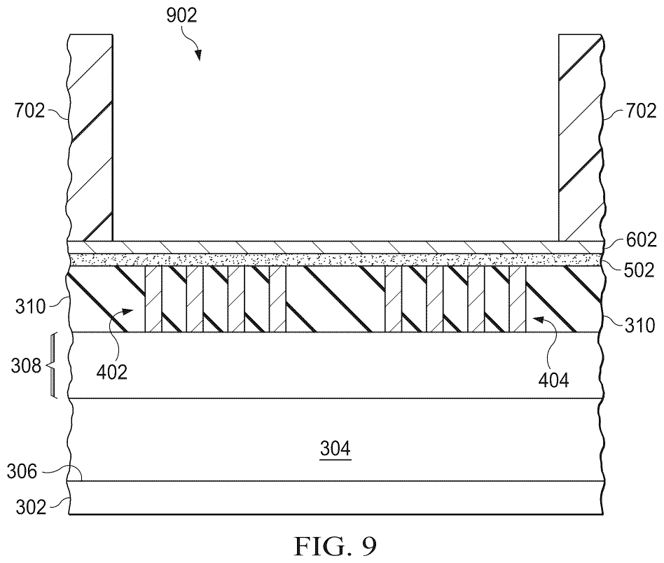

FIG. 9 illustrates an example of a seventh stage of the process flow. In the seventh stage, the photomask 802 and the nonirradiated portions are removed from the photoresist layer 702 (e.g., by an etch process) leaving a void 902. For example, a development process is performed on the photomask 802 and the nonirradiated portions of the photoresist layer 702 to form the void 902.

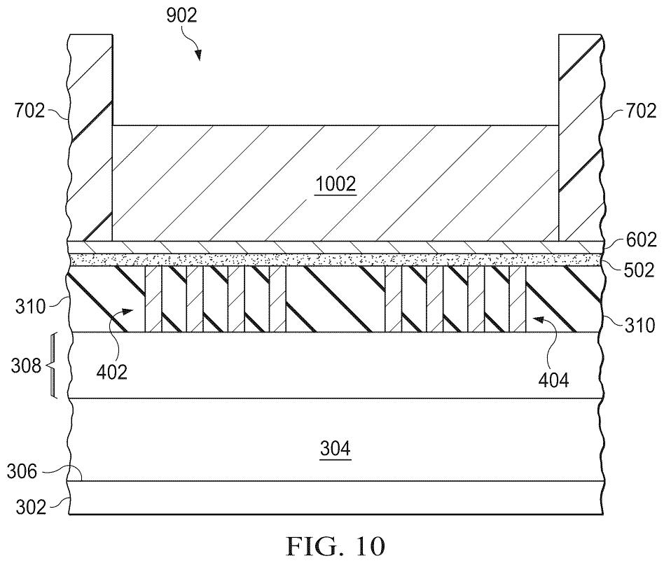

FIG. 10 illustrates an example of an eighth stage of the process flow. A multi-layer conductive contact is formed in the void 902. In the eighth stage, a first metal material is deposited in the void 902 over the seed layer 602 to form the first layer 1002 (e.g., the first layer 232 of FIG. 2B). The first metal material may be deposited in a sputter deposition or an electroplating operation. In some examples, the first metal material is the same material as the seed metal material used to form the seed layer 602. For example, given the seed metal material is Cu then the first metal material of the first layer 1002 is Cu.

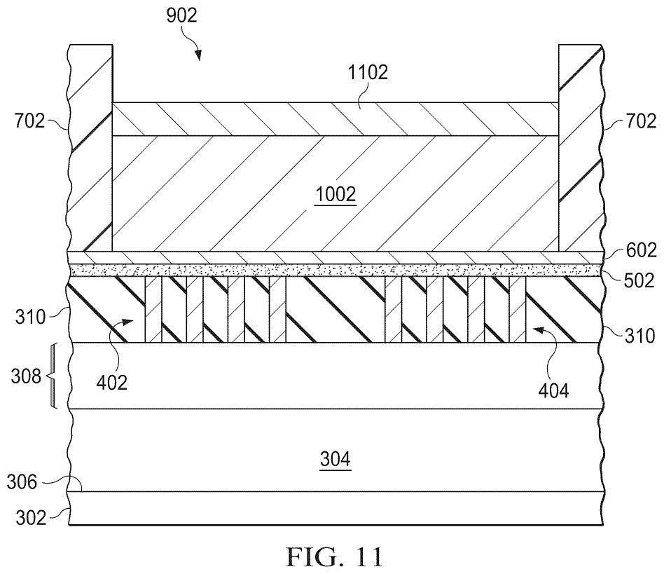

FIG. 11 illustrates an example of a ninth stage of the process flow. In the ninth stage, a second metal material is deposited in the void 902 over the first layer 1002 to form the second layer 1102 (e.g., the second layer 234 of FIG. 2B). The second metal material may be deposited in a sputter deposition or an electroplating operation. In some examples, the second metal material is a different metal material than the first metal material. For example, if the first metal material is Cu, then the second metal material is Ni.

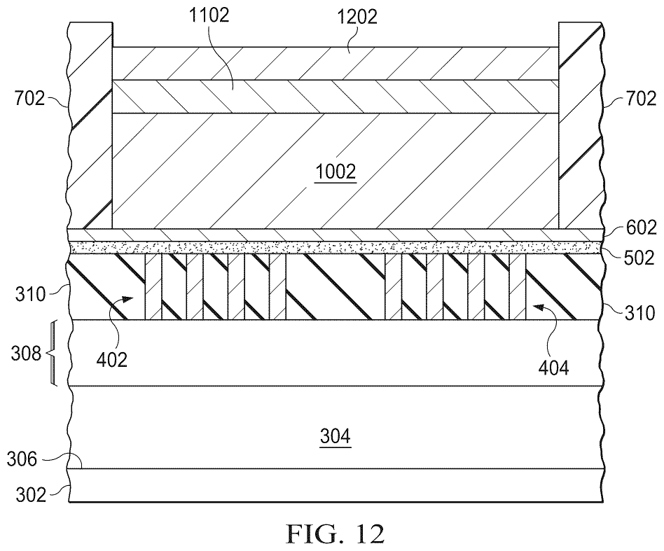

FIG. 12 illustrates an example of a tenth stage of the process flow. In the tenth stage, a third metal material is deposited in the void 902 over the second layer 1102 to form the third layer 1202 (e.g., the third layer 236 of FIG. 2B). The third metal material may be deposited in a sputter deposition or an electroplating operation. In some examples, the third metal material is a different metal material than the first metal material and the second metal material. For example, if the first metal material is Cu and the second metal material is Ni, then the third metal material is Pd. The resulting multi-layer conductive contact includes the first layer 1002, the second layer 1102, and the third layer 1202.

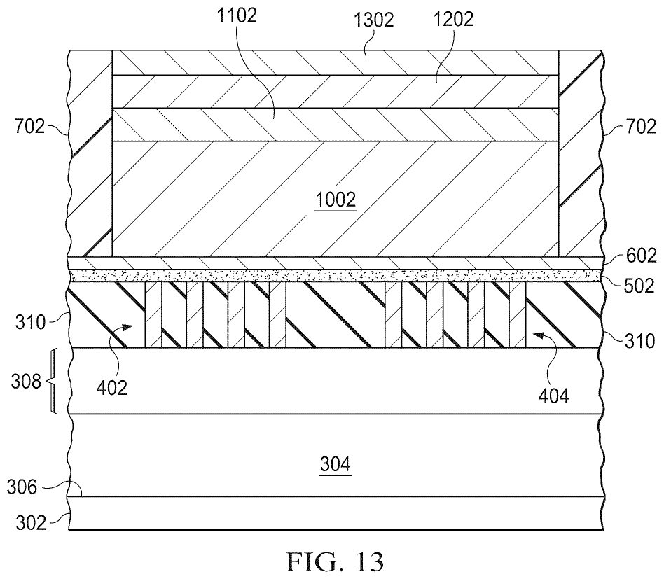

FIG. 13 illustrates an example of an eleventh stage of the process flow. In the eleventh stage, a sacrificial layer is formed. A sacrificial metal material is deposited over the third layer 1202 to form the sacrificial layer 1302. The sacrificial metal material may be deposited in a sputter deposition or an electroplating operation. In some examples, the sacrificial layer 1302 is the same as the seed metal material and first metal material, for example, Cu. Other conductive material (e.g., including metals and/or metal alloys) can be used in other examples.

The sacrificial layer 1302 has a sacrificial thickness in the second dimension and is the height of the sacrificial layer 1302 along the longitudinal axis (e.g., the longitudinal axis 202 of FIGS. 2A, 2B). The sacrificial thickness of the sacrificial layer 1302 is greater than the seed layer 602. In an example, the sacrificial thickness of the sacrificial layer 1302 is at least twice the seed thickness of the seed layer 602. For example, the sacrificial thickness of the sacrificial layer 1302 is from 1000 to 3000 Angstroms (from 0.10 to 0.30 micrometers—μm).

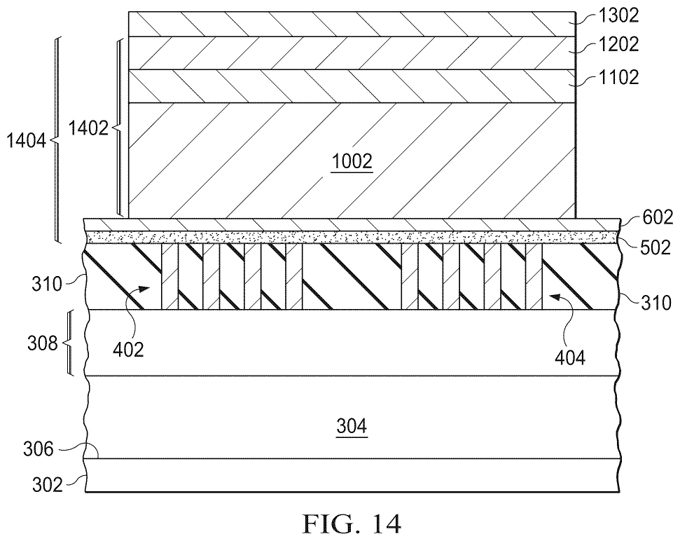

FIG. 14 illustrates an example of a twelfth stage of the process flow. In the twelfth stage, remaining portions of the photoresist layer 702 are removed from the seed layer 602 leaving a multi-layer conductive contact 1402 of a BOAC structure 1404 (e.g., the BOAC structure 226 of FIG. 2B). The multi-layer conductive contact 1402 having the plurality of different metal layers including a first layer 1002, a second layer 1102, and a third layer 1202 under the sacrificial layer 1302.

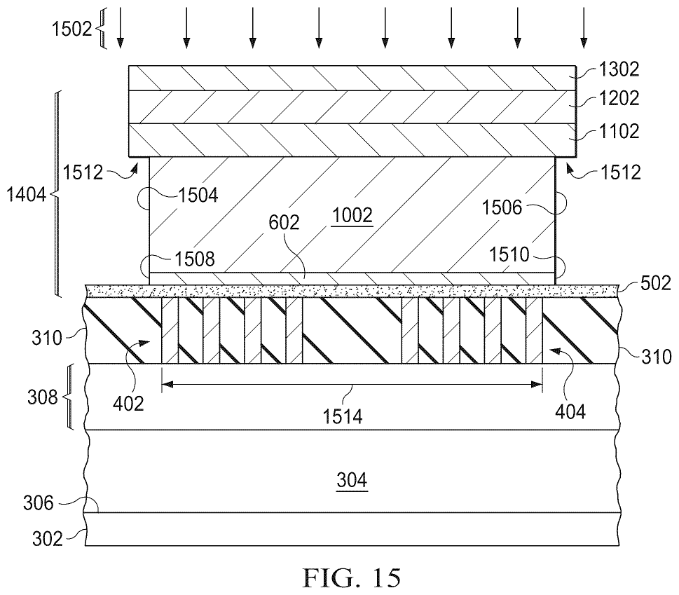

FIG. 15 illustrates an example of a thirteenth stage of the process flow. In the thirteenth stage, a first etch process 1502 is performed to remove portions of the seed layer 602 that extend beyond the width of the multi-layer conductive contact. For example, the first metal layer 1002 has a first sidewall 1504 opposite a second sidewall 1506 and the seed layer 602 has a first sidewall 1508 opposite a second sidewall 1510. The first etch process 1502 removes material from the first sidewall 1508 and the second sidewall 1510 of the seed layer 602. Because the first metal layer 1002 is made of a similar material as the seed layer 602, the first etch process 1502 may etch the first sidewall 1504 and the second sidewall 1506 of the first layer 1002 to align with the first sidewall 1508 and the second sidewall 1510 of the seed layer 602 thereby forming continuous sidewalls. In some examples, both of the sidewalls 1504, 1506 of the first layer 1002 and the sidewalls 1508, 1510 of the seed layer 602 are etched forming an undercut 1512 relative to the second layer 1102 and the third layer 1202.

During the first etch process 1502 the sacrificial layer 1302 is consumed by a metal etch. For example, the first etch process 1502 may be a copper etch. The duration of the etch process is based on the sacrificial thickness of the sacrificial layer 1302. The etch time of the first etch process 1502 may have a duration of thirty to eighty-six seconds, for example, eighty seconds. The sacrificial layer 1302 mitigates the impact of the galvanic effect during etching. In particular, the sacrificial layer 1302 acts as a protective layer that avoids the exposure of the third layer 1202 thereby minimizing the galvanic effect which reduces the undercut 1512 into the insulation layer 310 during etching. Accordingly, the contact width after the metal etch is greater than the via distance 1514.

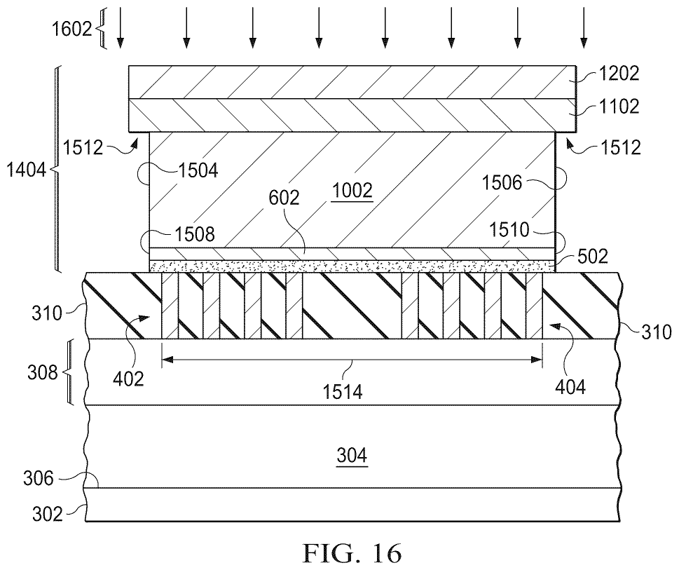

FIG. 16 illustrates an example of a fourteenth stage of the process flow. In the fourteenth stage, a second etch process 1602 is an adhesion etch to etch the adhesion layer 502. For example, the etch may be a titanium (Ti) or titanium-tungsten (TiW) etch. The etch time of the etch process 1602 may have a duration of approximately one hundred and twenty seconds. The etching reduces the adhesion layer 502 in the first dimension based on the width of the multi-layer conductive contact.

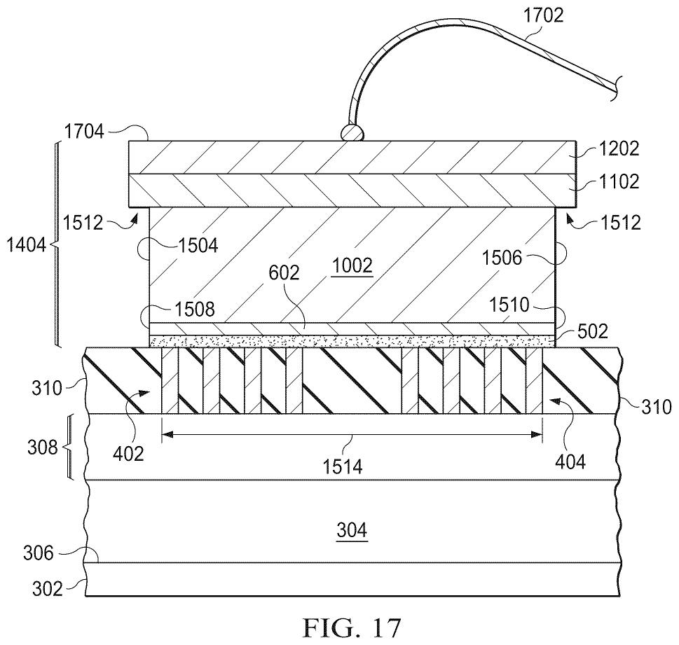

FIG. 17 illustrates an example of a fifteenth stage of the process flow. In the fifteenth stage, a bond wire 1702 is attached at the third layer 1202 of the BOAC structure 1404. For example, the bond wire 1702 forms an electrical connection between the die 302, at a top surface 1704 (e.g., the top surface 206 of FIG. 2B).

Additionally, a mold compound (e.g., the mold compound 116 of FIG. 1) is applied to cover the bond wire 1702, the multi-layer conductive contact, and the semiconductor die 302.

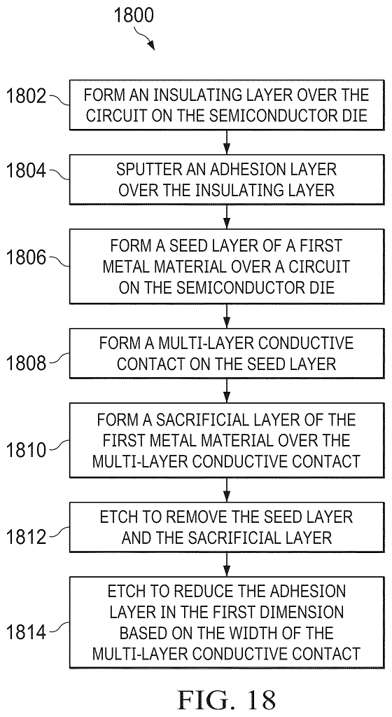

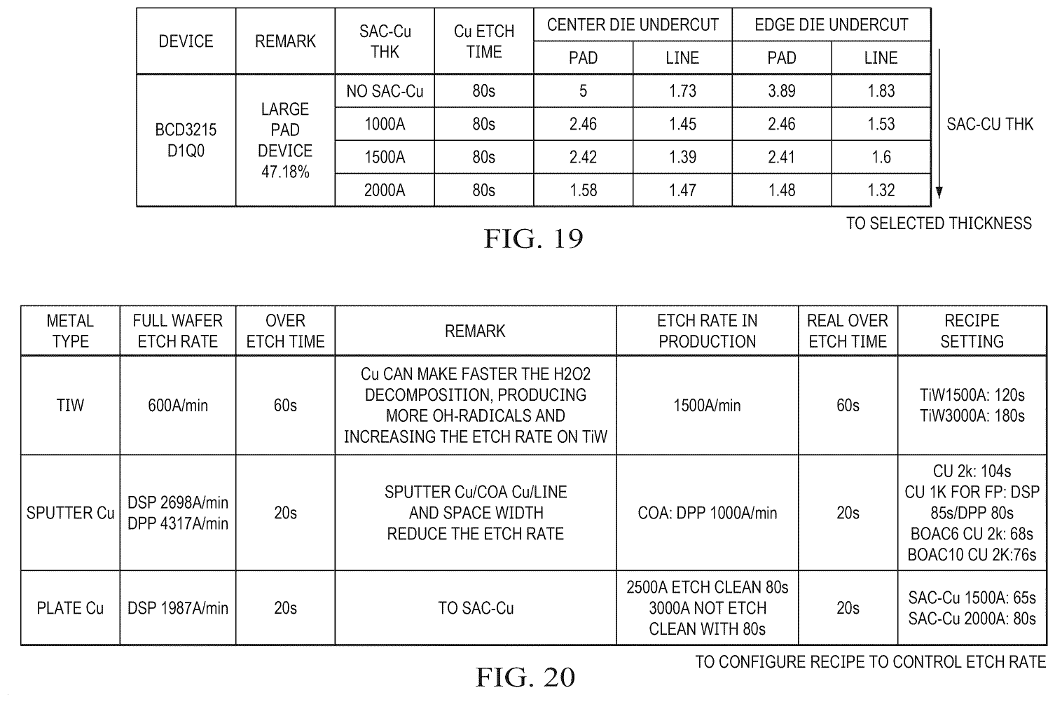

FIG. 18 illustrates a flowchart of an example method for forming a semiconductor device using a sacrificial layer. For simplicity, the method 1800 will be described as a sequence of blocks, but it is understood that the elements of the method 1800 can be organized into different architectures, elements, stages, and/or processes.

At block 1802, the method 1800 includes forming an insulating layer (e.g., the insulating layer 110 of FIG. 1, the insulating layer 216 of FIG. 2B, the insulating layer 310 of FIG. 3) over the active circuit (e.g., the active circuit 104 of FIG. 1, the active circuit 212 of FIG. 2B, the active circuit 304 of FIG. 3) on the device side (e.g., the device side 106 of FIG. 1, the device side 306 of FIG. 3) of the semiconductor die (e.g., the semiconductor die 302 of FIG. 3).

At block 1804, the method 1800 includes sputtering an adhesion layer (e.g., the adhesion layer 228 of FIG. 2B, the adhesion layer 502 of FIG. 5) over the insulating layer.

At block 1806, the method 1800 includes forming a seed layer (e.g., the seed layer 230 of FIG. 2B, the seed layer of FIG. 6) of a first metal material over the circuit on the device side of the semiconductor die.

At block 1808, the method 1800 includes forming a multi-layer conductive contact on the seed layer. The multi-layer conductive contact has a width in a first dimension and includes a plurality of layers (e.g., the first layer 1002 of FIG. 12, the second layer 1102 of FIG. 12, the third layer of FIG. 1202 of FIG. 12) of different metal materials and a portion of the seed layer extends outwardly from a periphery (e.g., the periphery 238 of FIG. 2B) of the multi-layer conductive contact.

At block 1810, the method 1800 includes forming a sacrificial layer (e.g., the sacrificial layer 1302 of FIG. 13) of the first metal material over the multi-layer conductive contact.

At block 1812, the method 1800 includes etching (e.g., the etching process 1502 of FIG. 15) to remove the seed layer and the sacrificial layer.

At block 1814, the method 1800 includes etching (e.g., the second etching process 1602 of FIG. 16) to reduce the adhesion layer in the first dimension based on the width of the multi-layer conductive contact.

The galvanic effect is proportional to the area of the third layer such that the more Pd, the greater the undercut 1512 into the insulation layer during etching. Conventional techniques for reducing the impact of the galvanic effect may limit the design of the semiconductor chip packages. For example, reducing the etching time risks inadequate etching of the seed layer. In the semiconductor devices and methods described herein, a sacrificial layer is formed over the multi-layer conductive contact to mitigate the impact of the galvanic effect during etching. The sacrificial layer acts as a protective layer that avoids the exposure of the third layer of Pd thereby minimizing the galvanic effect which reduces the undercut 1512 into the first layer 1002 during etching.

The duration of the metal etch is based on the sacrificial thickness of the sacrificial layer (e.g., the sacrificial layer 1302 of FIG. 13). For example, FIG. 20 illustrates a table showing the thickness of a sacrificial layer relative to the amount of undercutting of the semiconductor device.

Other characteristics (e.g., metal material, etch rate, thickness, etc.) of the metal etch is based on the sacrificial thickness of the sacrificial layer. FIG. 21 illustrates a table etching characteristics based on the layer being etched.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

A “value” as used herein may include, but is not limited to, a numerical or other kind of value or level such as a percentage, a non-numerical value, a discrete state, a discrete value, a continuous value, among others. The term “value of X” or “level of X” as used throughout this detailed description and in the claims refers to any numerical or other kind of value for distinguishing between two or more states of X. For example, in some cases, the value of X may be given as a percentage between 0% and 100%. In other cases, the value of X could be a value in the range between 1 and 10. In still other cases, the value of X may not be a numerical value, but could be associated with a given discrete state, such as “not X”, “slightly x”, “x”, “very x”and “extremely x”.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming an integrated circuit (IC), comprising:
forming a seed layer of a first metal material over a circuit on a device side of a semiconductor die;
forming a multi-layer conductive contact on the seed layer, wherein the multi-layer conductive contact has a width in a first dimension and includes a plurality of layers of different metal materials and a portion of the seed layer extends outwardly from a periphery of the multi-layer conductive contact;
forming a sacrificial layer of the first metal material over the multi-layer conductive contact; and
etching to remove the seed layer and the sacrificial layer.

2. The method of claim 1, wherein the multi-layer conductive contact includes a first layer of the first metal material, a second layer of a second metal material over the first layer, and a third layer of a third metal material.

3. The method of claim 2, wherein the first metal material is copper (Cu).

4. The method of claim 2, wherein the second metal material is nickel (Ni) and the third metal material is palladium (Pd).

5. The method of claim 1, wherein the seed layer has a seed thickness in a second dimension approximately orthogonal to the first dimension, and the sacrificial layer has a sacrificial thickness in the second dimension that is greater than the seed thickness.

6. The method of claim 5, wherein the sacrificial thickness is greater than the seed thickness.

7. The method of claim 5, wherein the sacrificial thickness approximately 1,000 angstroms.

8. The method of claim 1, further comprising:
forming an insulating layer over the circuit on the device side of the semiconductor die;
sputtering an adhesion layer between the insulating layer and the seed layer; and
etching to reduce the adhesion layer in the first dimension based on the width of the multi-layer conductive contact.

9. The method of claim 8, wherein the adhesion layer is formed of titanium-tungsten (TiW) and titanium (Ti) is co-sputtered with tungsten (W).

10. The method of claim 1, further comprising:
attaching a bond wire between the semiconductor die and the multi-layer conductive contact; and
applying a mold compound to cover the bond wire, the multi-layer conductive contact, and the semiconductor die.

11. A packaged semiconductor device produced according to the method of claim 10.

12. A method of forming a bond over active circuit (BOAC) semiconductor device, comprising:
forming an insulating layer over a circuit on a device side of a semiconductor die, wherein the insulating layer includes a number of vias separated in a first dimension extending from a first outer via to a second outer via as a via distance;
forming a seed layer of a first metal material over the insulating layer;
forming a multi-layer conductive contact electrically coupled to the circuit, wherein the multi-layer conductive contact comprises a top surface that is spaced away from the circuit, wherein the multi-layer conductive contact has a contact width in the first dimension and includes a plurality of layers of different metal materials;
forming a sacrificial layer over the multi-layer conductive contact, wherein the sacrificial layer is formed of the first metal material; and
performing a metal etch to reduce the seed layer in the first dimension based on the contact width of the multi-layer conductive contact and remove the sacrificial layer, wherein the contact width after the metal etch is greater than the via distance.

13. The method of claim 12, wherein the multi-layer conductive contact includes a first layer of the first metal material that forms a bottom surface of the multi-layer conductive contact, a second layer of a second metal material over the first layer, and a third layer of a third metal material that forms the top surface of the multi-layer conductive contact.

14. The method of claim 13, wherein the first metal material is copper (Cu).

15. The method of claim 13, wherein the second metal material is nickel (Ni) and the third metal material is palladium (Pd).

16. The method of claim 12, wherein the seed layer has a seed thickness in a second dimension approximately orthogonal to the first dimension, and the sacrificial layer has a sacrificial thickness in the second dimension that is greater than the seed thickness.

17. The method of claim 16, wherein the sacrificial thickness is greater than the seed thickness.

18. The method of claim 16, wherein the sacrificial thickness approximately 1,000 angstroms.

19. The method of claim 12, further comprising:
sputtering an adhesion layer between the insulating layer and the seed layer; and
performing an adhesion etch after the metal etch to reduce the adhesion layer in the first dimension based on the contact width of the multi-layer conductive contact.

20. The method of claim 19, wherein the adhesion layer is formed of titanium-tungsten (TiW) and titanium (Ti) is co-sputtered with tungsten (W).

21. The method of claim 12, further comprising:
attaching a bond wire between the semiconductor die and the multi-layer conductive contact; and
applying a mold compound to cover the bond wire, the multi-layer conductive contact, and the semiconductor die.

22. A semiconductor device produced according to the method of claim 12, wherein the multi-layer conductive contact has opposing spaced apart sidewalls that define the contact width that is greater than the via distance.

23. An integrated circuit (IC), comprising:
a circuit on a device side of a semiconductor die;
an insulating layer over the circuit, the insulating layer including a number of vias separated from each other and arranged from a first outer via to a second outer via, wherein the first outer via and the second outer via are spaced apart a via distance;
a seed layer of a first metal material over the insulating layer; and
a multi-layer conductive contact over the seed layer and electrically coupled to the circuit through at least some of the vias, wherein the multi-layer conductive contact comprises a top surface that is spaced from the circuit, wherein the multi-layer conductive contact has opposing spaced apart sidewalls that define a contact width that is greater than the via distance.

24. The IC of claim 23, wherein the multi-layer conductive contact includes a first layer of the first metal material, a second layer of a second metal material over the first layer, and a third layer of a third metal material.

25. The IC of claim 24, wherein the first metal material is copper (Cu).

26. The IC of claim 24, wherein the second metal material is nickel (Ni) and the third metal material is palladium (Pd).

27. The IC of claim 23, further comprising:
a bond wire attached at the semiconductor die and the multi-layer conductive contact.
